(19) United States
(12) Patent Application Publication
(10) Pub. No.: US 2019/0207127 A1
(43) Pub. Date: Jul. 4, 2019

(54) ORGANIC METAL COMPOUND AND ORGANIC LIGHT-EMITTING DEVICES EMPLOYING THE SAME

(71) Applicant: INDUSTRIAL TECHNOLOGY RESEARCH INSTITUTE, Hsinchu (TW)

(72) Inventors: Jin-Sheng LIN, Taipei City (TW); Pang-Chi HUANG, Taoyuan City (TW); Yung-Chen CHENG, Xiushui Township (TW); Ching-Hui CHOU, Hsinchu City (TW); Jia-Lun LIOU, Hengshan Township (TW); Meng-Hao CHANG, New Taipei City (TW); Mei-Rurng TSENG, Hsinchu City (TW)

(73) Assignee: INDUSTRIAL TECHNOLOGY RESEARCH INSTITUTE, Hsinchu (TW)

(21) Appl. No.: 16/027,617

(22) Filed: Jul. 5, 2018

(30) Foreign Application Priority Data
Dec. 28, 2017 (TW) 106146227

(51) Int. Cl. H01L 51/00; C07F 15/00

(52) U.S. Cl. CPC H01L 51/0085; H01L 51/5016; H01L 51/0025; C07F 15/0033

(57) ABSTRACT

Organic metal compounds and organic light-emitting devices employing the same are provided. The organic metal compound has a chemical structure of Formula (I) or Formula (II):

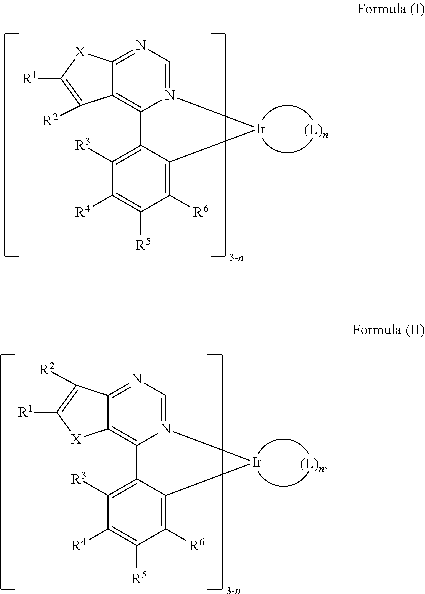

wherein X is O or S; L is

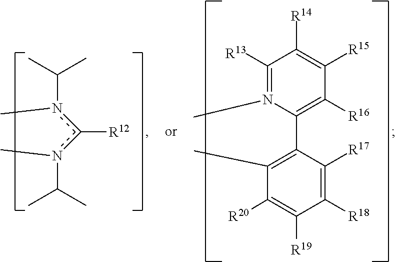

R¹² is

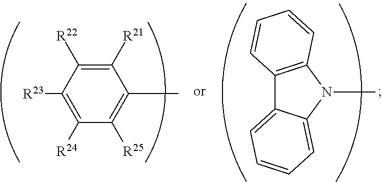

and, n is 0, 1, or 2.

### CROSS REFERENCE TO RELATED APPLICATIONS

The application is based on, and claims priority from, Taiwan Application Serial Number 106146227, filed on Dec. 28, 2017, the disclosure of which is hereby incorporated by reference herein in its entirety.

### TECHNICAL FIELD

The disclosure relates to an organic metal compound and an organic light-emitting device employing the same.

### BACKGROUND

An organic light-emitting diode (OLED) is a light-emitting diode employing an organic electroluminescent layer as an active layer. OLED display devices have high luminescent efficiency and long operating lifespans. Unlike liquid-crystal displays, a device employing an organic light-emitting diode does not need a back-light source thanks to spontaneous emission.

Generally, an organic light-emitting device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop highly efficient phosphorescent material, in order to increase the emissive efficiency of an OLED.

### SUMMARY

According to embodiments of the disclosure, the disclosure provides an organic metal compound, which has a structure represented by Formula (I) or Formula (II)

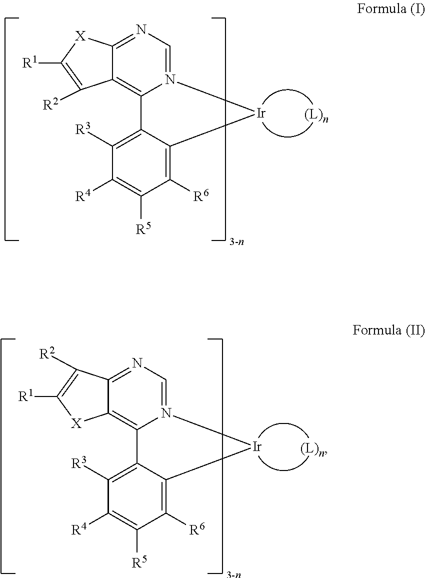

wherein X is O or S; R¹ is independently hydrogen, halogen, C₁₋₈ alkyl group, C₁₋₈ haloalkyl group, C₁₋₈ alkoxy group, C₅₋₁₀ cycloalkyl group, or

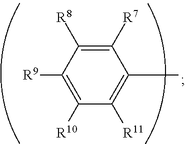

R², R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; L is

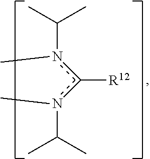

or

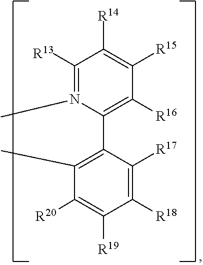

wherein R¹² is

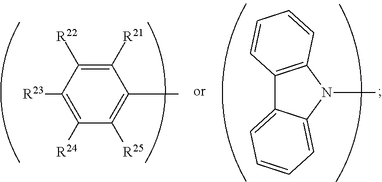

R¹³, R¹⁴, R¹⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group; R²¹, R²², R²³, R²⁴ and R²⁵ are independently hydrogen, halogen, C₁₋₈ alkyl group, C₁₋₈ haloalkyl group, or C₁₋₈ alkoxy group; and, n is 0, 1, or 2.

According to another embodiment of the disclosure, the disclosure provides an organic light-emitting device. The organic light-emitting device includes a pair of electrodes and an organic light-emitting element disposed between the electrodes, wherein the organic light-emitting element includes the aforementioned organic metal compound.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a cross section of an organic light-emitting device disclosed by an embodiment of the disclosure.

### DETAILED DESCRIPTION

In the following detailed description, for the purposes of explanation, numerous specific details are set forth in order to provide a thorough understanding of the disclosed embodiments. It will be apparent, however, that one or more embodiments may be practiced without these specific details. In other instances, well-known structures and devices are shown schematically in order to simplify the drawing.

According to embodiments of the disclosure, the organic metal compound of the disclosure is a six-coordinate iridium compound having at least one of thiopyrimidine-based (or furopyrimidine-based) ligand and having a phenylpyridine-based ligand (such as methylphenylpyridine (mppy) ligand or diisopropyl carbodiimide ligand). Accordingly, the organic metal compound of the disclosure can exhibit a red-shifted emission and facilitate the electrons recombining with the holes to form excitons, resulting in enhancing the luminescent efficiency of the organic light-emitting device employing the organic metal compound. In addition, since the ligand of high thermal stability is introduced into the organic metal compound of the disclosure and the conjugation length of the organic metal compound is extended by the ligand, the organic metal compound of the disclosure exhibits high electrochemical stability and thermal stability and is suitable for being purified by a sublimation process (the organic metal compound of the disclosure has a sublimation yield that is between 80% and 90% at a sublimation temperature less than 260° C.). The organic light-emitting device employing the organic metal compound can exhibit high operating lifespan and luminescent efficiency.

According to embodiments of the disclosure, the disclosure provides an organic metal compound having a structure represented by Formula (I) or Formula (II):

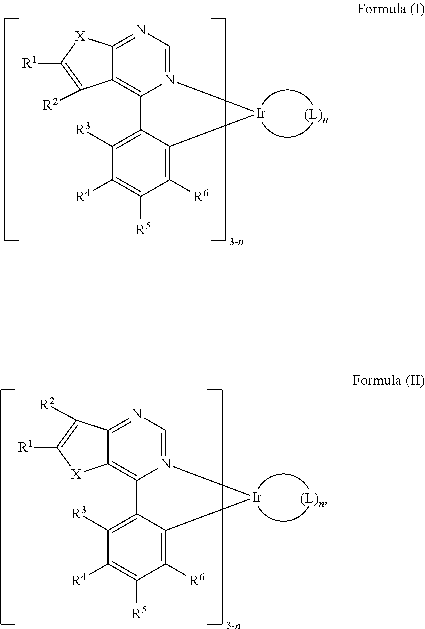

wherein X is O or S; R¹ is independently hydrogen, halogen, C₁₋₈ alkyl group, C₁₋₈ haloalkyl group, C₁₋₈ alkoxy group, C₅₋₁₀ cycloalkyl group, or

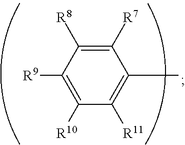

R², R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; L is

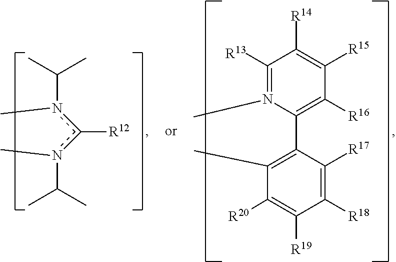

wherein R¹² is

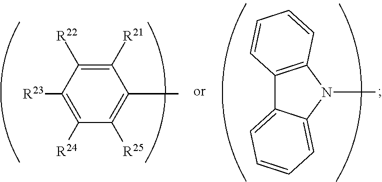

R¹³, R¹⁴, R¹⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group; R²¹, R²², R²³, R²⁴ and R²⁵ are independently hydrogen, halogen, C₁₋₈ alkyl group, C₁₋₈ haloalkyl group, or C₁₋₈ alkoxy group; and, n is 0, 1, or 2.

According to embodiments of the disclosure, C₁₋₈ alkyl group can be linear or branched alkyl group. For example, C₁₋₈ alkyl group can be methyl group, ethyl group, propyl group, iso-propyl group, n-butyl group, tert-butyl group, sec-butyl group, iso-butyl group, pentyl group or hexyl group. According to embodiments of the disclosure, C₁₋₈ haloalkyl group can be an alkyl group which a part of or all hydrogen atoms bonded on the carbon atom are replaced with halogen atoms, and C₁₋₈ haloalkyl group can be linear or branched haloalkyl group. For example, fluoromethyl group can be monofluoromethyl group, difluoromethyl group or trifluoromethyl group. According to embodiments of the disclosure, C₁₋₈ alkoxy group can be linear or branched alkoxy group. For example, C₁₋₈ alkoxy group can be methoxy group, ethoxy group, propoxy group, isopropoxy group, butoxy group, sec-butoxy group, iso-butoxy group, tert-butoxy group, pentyloxy group, or hexyloxy group. According to embodiments of the disclosure, C₅₋₁₀ cycloalkyl group can be cyclopentyl or cyclohexyl. According to embodiments of the disclosure, C₆₋₁₂ aryl group can be phenyl, biphenyl, or naphthyl.

According to embodiments of the disclosure, R¹, R², R³, R⁴, R⁵ and R⁶ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to embodiments of the disclosure, R¹ can be

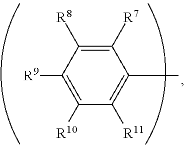

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

According to embodiments of the disclosure, L can be

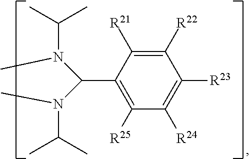

wherein R²¹, R²², R²³, R²⁴ and R²⁵ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

According to some embodiments of the disclosure, L can be

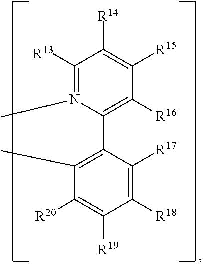

wherein R¹³, R¹⁴, R¹⁵, R¹⁶, R¹⁷, R¹⁸, R¹⁹ and R²⁰ is independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to some embodiments of the disclosure, the organic metal compound can be

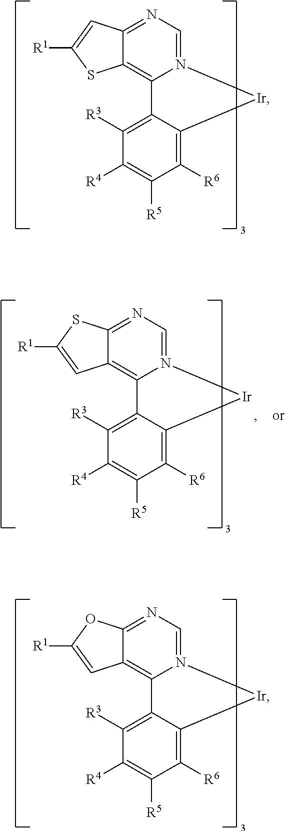

wherein R¹ can be independently hydrogen, halogen, C₁₋₈ alkyl group, C₁₋₈ haloalkyl group, C₁₋₈ alkoxy group, C₅₋₁₀ cycloalkyl group, or

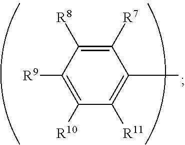

R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group. For example, R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group. In addition, R¹ can be

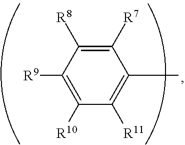

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

According to some embodiments of the disclosure, the organic metal compound is

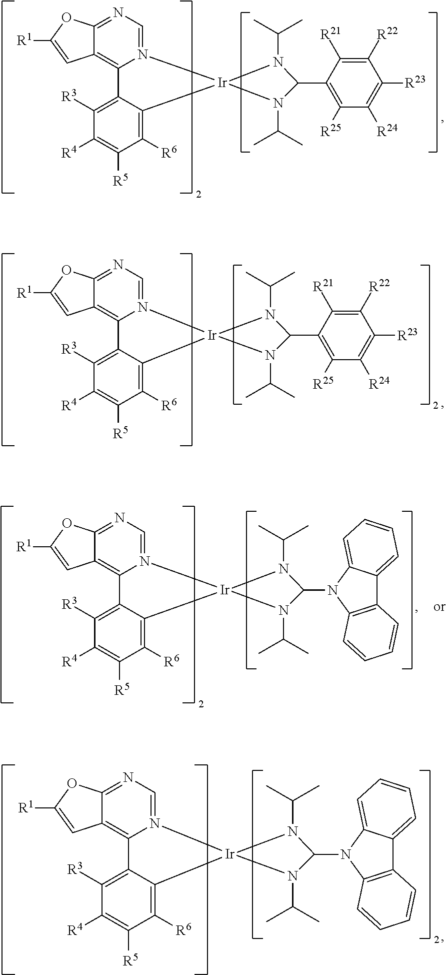

wherein R¹ is independently hydrogen, halogen, C₁₋₈ alkyl group, C₁₋₈ haloalkyl group, C₁₋₈ alkoxy group, C₅₋₁₀ cycloalkyl group, or

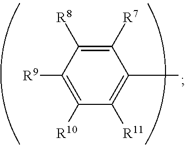

R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; R⁷, R⁸, R⁹, R¹⁰ and R¹¹ are independently hydrogen, halogen, C₆₋₁₂ aryl group, C₁₋₈ alkyl group, C₁₋₈ haloalkyl group, or C₁₋₈ alkoxy group; and, R²¹, R²², R²³, R²⁴ and R²⁵ are independently hydrogen, halogen, C₁₋₈ alkyl group, C₁₋₈ haloalkyl group, or C₁₋₈ alkoxy group. For example, R¹, R³, R⁴, R⁵ and R⁶ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group. In addition, R¹ can be

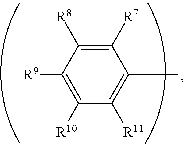

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group. For example, R²¹, R²², R²³, R²⁴ and R²⁵ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

According to some embodiments of the disclosure, the organic metal compound can be

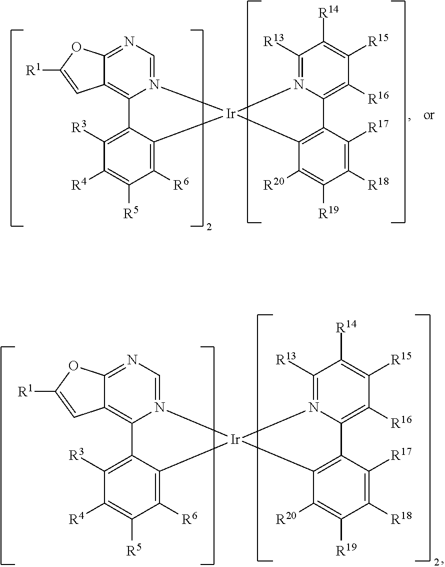

wherein R¹ can be independently hydrogen, halogen, C₁₋₈ alkyl group, C₁₋₈ haloalkyl group, C₁₋₈ alkoxy group, C₅₋₁₀ cycloalkyl group, or

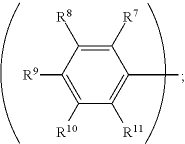

R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R¹³, R¹⁴, R⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group. For example, R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group. In addition, R¹ is

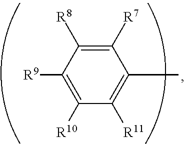

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group. For example, R¹³, R¹⁴, R¹⁵, R¹⁶, R¹⁷, R¹⁸, R¹⁹ and R²⁰ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to some embodiments of the disclosure, the organic metal compound can be

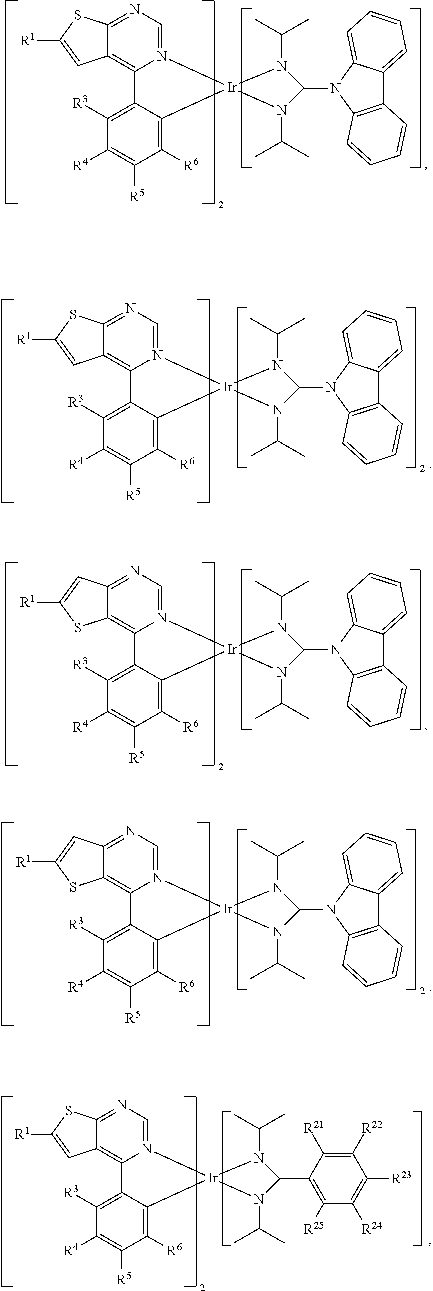

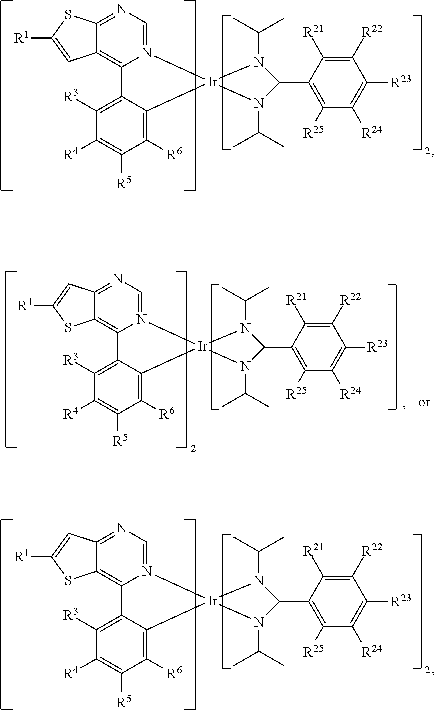

wherein R¹ can be independently hydrogen, halogen, C₁₋₈ alkyl group, C₁₋₈ haloalkyl group, C₁₋₈ alkoxy group, C₅₋₁₀ cycloalkyl group, or

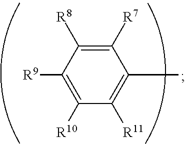

R³, R¹, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R²¹, R²², R²³, R²⁴ and R²⁵ are independently hydrogen, halogen, C₁₋₈ alkyl group, C₁₋₈ haloalkyl group, or C₁₋₈ alkoxy group. For example, R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group. In addition, R¹ can be

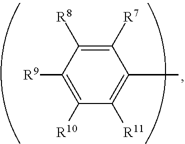

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group. For example, R²¹, R²², R²³, R²⁴ and R²⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

According to some embodiments of the disclosure, the organic metal compound can be

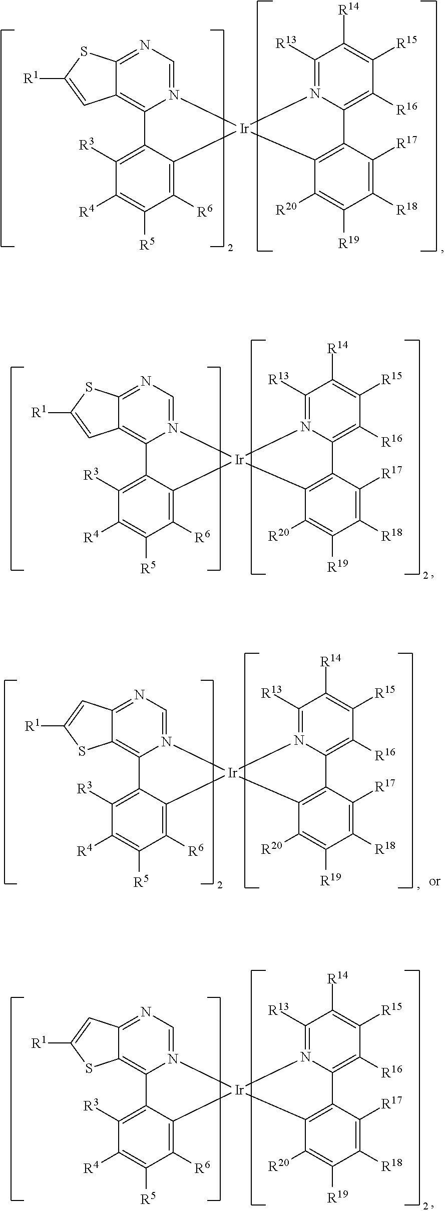

wherein R¹ is independently hydrogen, halogen, C₁₋₈ alkyl group, C₁₋₈ haloalkyl group, C₁₋₈ alkoxy group, C₅₋₁₀ cycloalkyl group, or

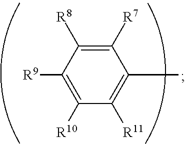

R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R¹³, R¹⁴, R¹⁵, R¹⁶, R¹⁷, R¹⁸, R¹⁹ and R²⁰ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group.

For example, R¹, R³, R⁴, R⁵ and R⁶ can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

R¹ can be

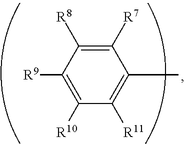

wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

For example, R¹³, R¹⁴, R¹⁵, R¹⁶, R¹⁷, R¹⁸, R¹⁹ and R²⁰ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

The organic metal compounds having the structure represented by Formula (I) or Formula (II) of the disclosure include the following compounds shown in Table 1 and the structures thereof are shown in Table 1.

TABLE 1

| | structure of organic metal compound | |
|---|---|---|
| Example 1 | 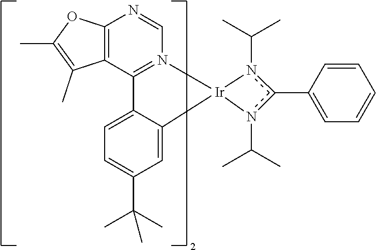 | Organic metal compound (I) |
| Example 2 | 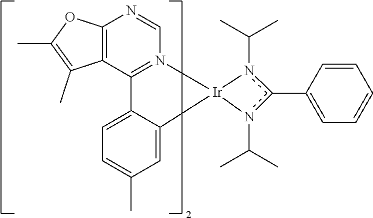 | Organic metal compound (II) |
| Example 3 | 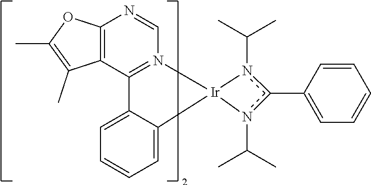 | Organic metal compound (III) |
| Example 4 | 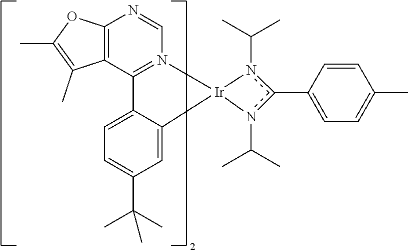 | Organic metal compound (IV) |
| Example 5 | 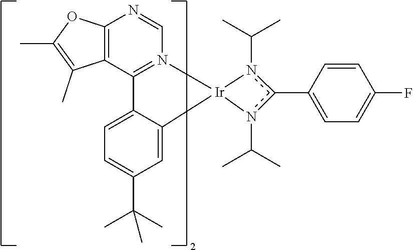 | Organic metal compound (V) |
| Example 6 | 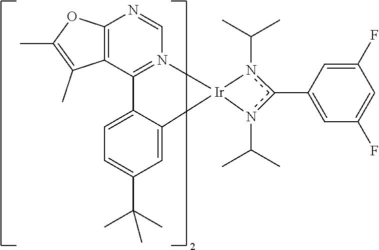 | Organic metal compound (VI) |
| Example 7 | 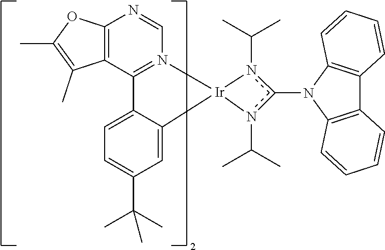 | Organic metal compound (VII) |
| Example 8 | 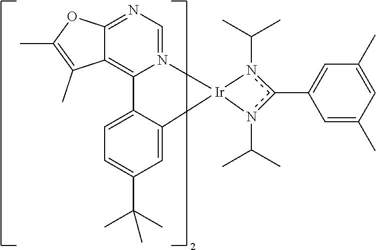 | Organic metal compound (VIII) |
| Example 9 | 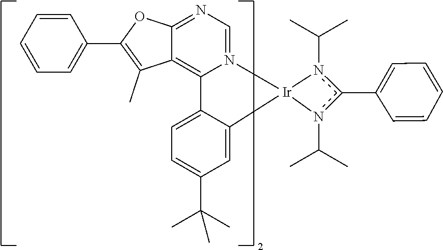 | Organic metal compound (IX) |
| Example 10 | 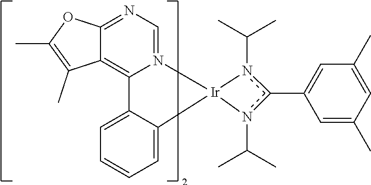 | Organic metal compound (X) |
| Example 11 | 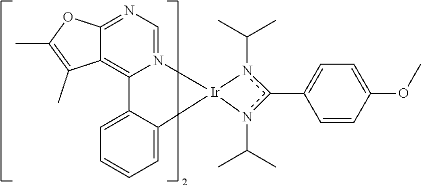 | Organic metal compound (XI) |
| Example 12 | 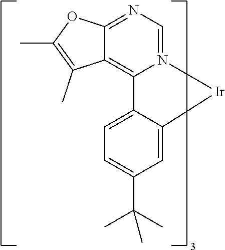 | Organic metal compound (XII) |
| Example 13 | 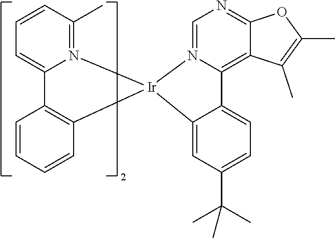 | Organic metal compound (XIII) |
| Example 14 | 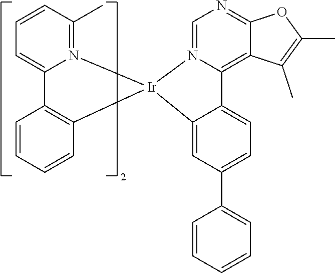 | Organic metal compound (XIV) |
| Example 15 | 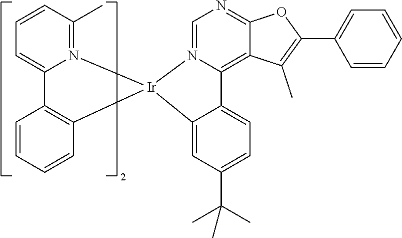 | Organic metal compound (XV) |
| Example 16 | 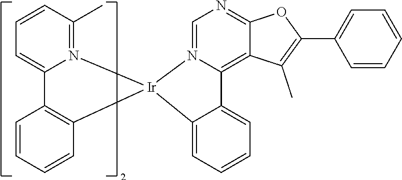 | Organic metal compound (XVI) |
| Example 17 | 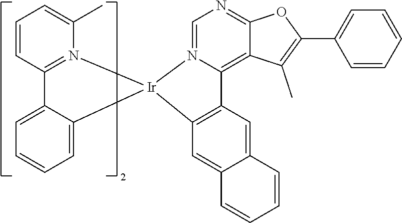 | Organic metal compound (XVII) |
| Example 18 | 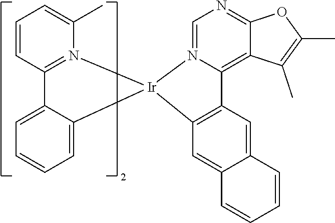 | Organic metal compound (XVIII) |
| Example 19 | 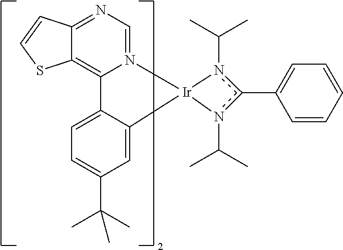 | Organic metal compound (XIX) |
| Example 20 | 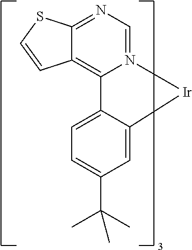 | Organic metal compound (XX) |
| Example 21 | 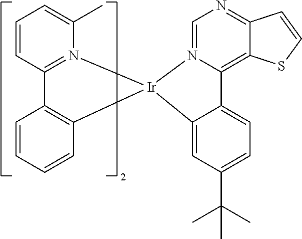 | Organic metal compound (XXI) |
| Example 22 | 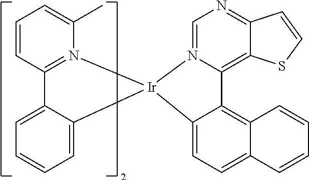 | Organic metal compound (XXII) |
| Example 23 | 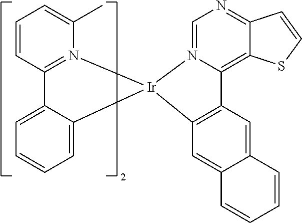 | Organic metal compound (XXIII) |
| Example 24 | 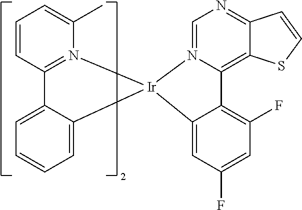 | Organic metal compound (XXIV) |
| Example 25 | 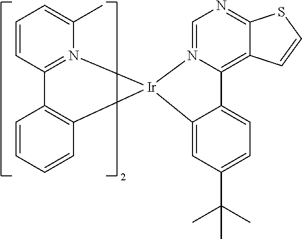 | Organic metal compound (XXV) |
| Example 26 | 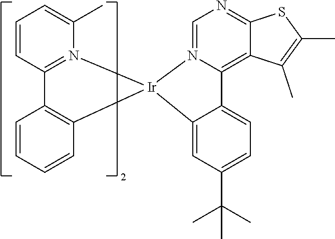 | Organic metal compound (XXVI) |
| Example 27 | 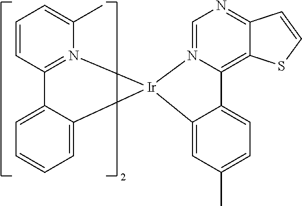 | Organic metal compound (XXVII) |
| Example 28 | 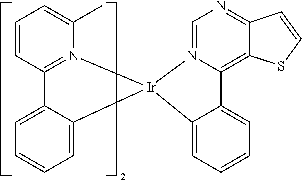 | Organic metal compound (XXVIII) |
| Example 29 | 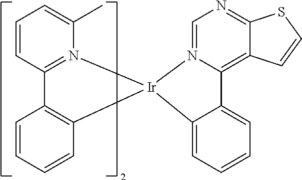 | Organic metal compound (XXIX) |
| Example 30 | 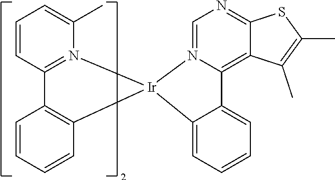 | Organic metal compound (XXX) |
| Example 31 | 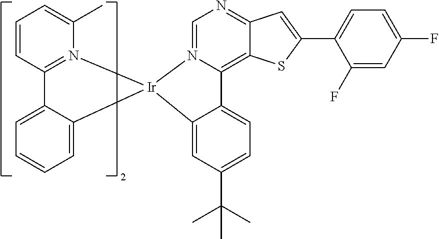 | Organic metal compound (XXXI) |
| Example 32 | 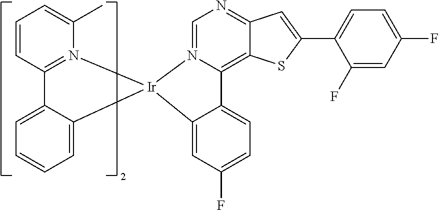 | Organic metal compound (XXXII) |
| Example 33 | 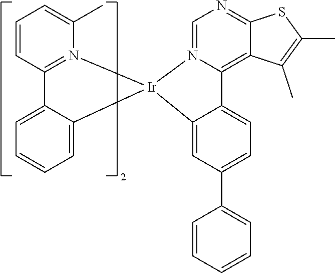 | Organic metal compound (XXXIII) |
| Example 34 | 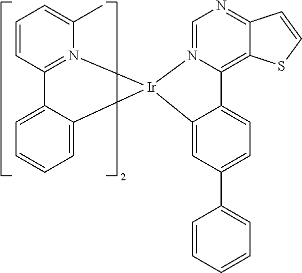 | Organic metal compound (XXXIV) |
| Example 35 | 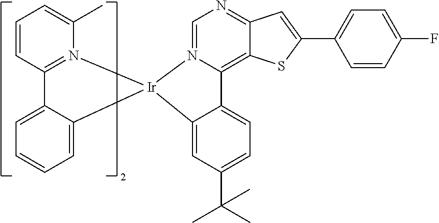 | Organic metal compound (XXXV) |
| Example 36 | 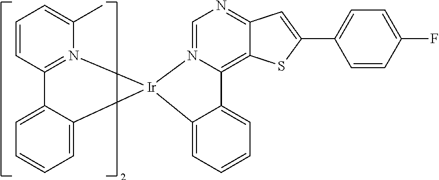 | Organic metal compound (XXXVI) |
| Example 37 | 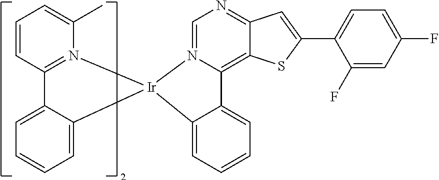 | Organic metal compound (XXXVII) |
| Example 38 | 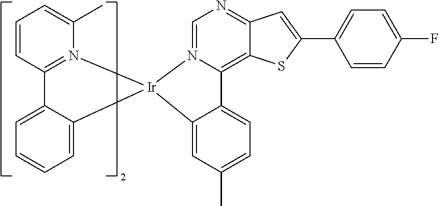 | Organic metal compound (XXXVIII) |
| Example 39 | 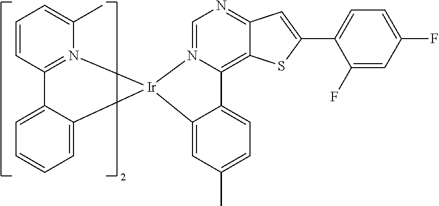 | Organic metal compound (XXXIX) |

In order to clearly illustrate the method for preparing the organic metal compound of the disclosure, the preparation of compounds disclosed in Examples 1-4, 12, 15-16, 28-29, 35 and 38 are described in detail below.

Preparation of Organic Metal Compound (I)

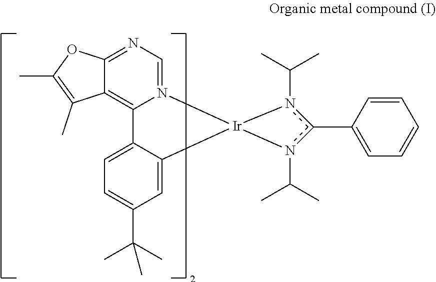

A reaction bottle was provided, and Compound (1) (1.54 mmole) and iridium trichloride (IrCl₃) (0.7 mmole), 2-methoxyethanol (15 mL) and water (5 mL) were added into the reaction bottle. Next, after removing moisture and purging nitrogen gas several times, the reaction bottle was heated to reflux. After reacting for 24 hr, the reaction bottle was cooled to room temperature. After adding water into the reaction bottle and filtrating, the filter cake was washed with water and methanol. After drying by a vacuum, Compound (2) was obtained. The synthesis pathway of the above reaction was as follows:

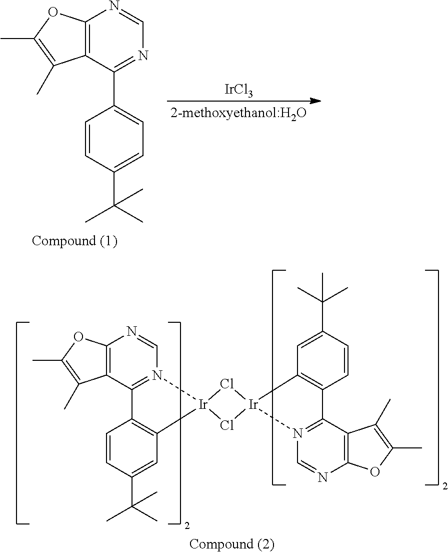

Next, 10 mL of tetrahydrofuran (THF) and bromobenzene (3.2 mmole) were added into a reaction bottle. After cooling to −78° C., n-butyl lithium (n-BuLi) (3.2 mmole) was added dropwise into the reaction bottle and the result was stirred for 30 min. Next, N,N-diisopropylcarbodiimide (3.2 mmole) was added into the reaction bottle at −78° C. After stirring for 30 min, the result was added dropwise into a solution including Compound (2) (0.8 mmole of Compound (2) dissolved in 14 mL of tetrahydrofuran (THF)). Next, the reaction bottle was heated to reflux. After reacting for 8 hr, the result was concentrated by rotary evaporator, and then purified by column chromatography, obtaining Organic metal compound (I). The synthesis pathway of the above reaction was as follows:

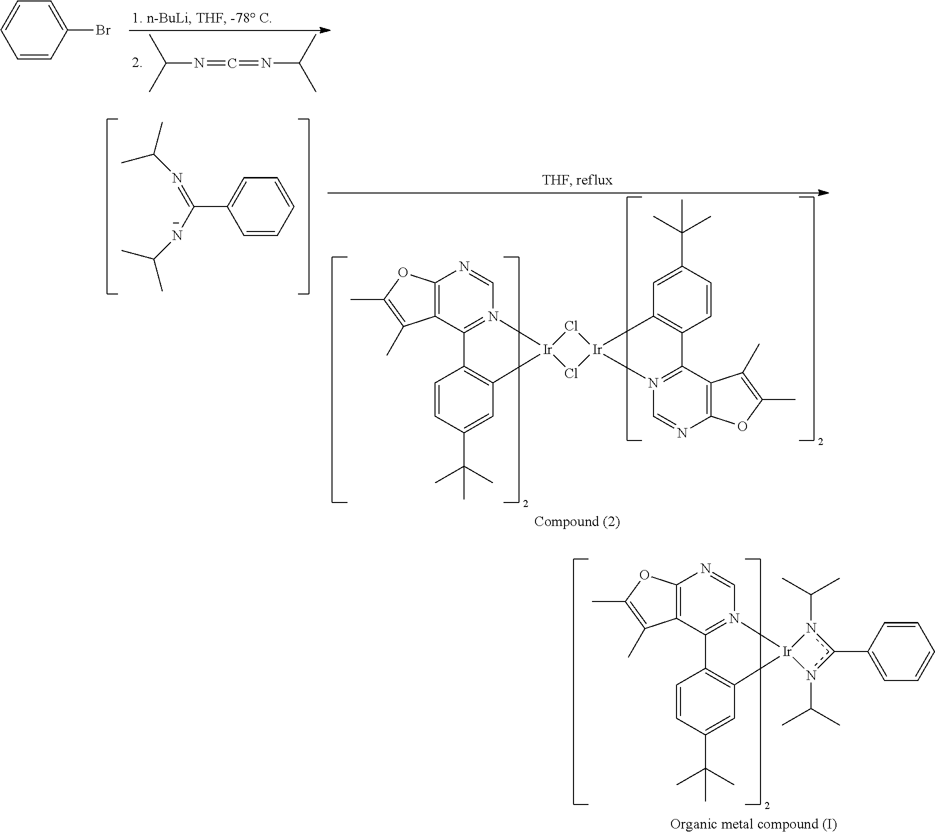

Preparation of Organic Metal Compound (II)

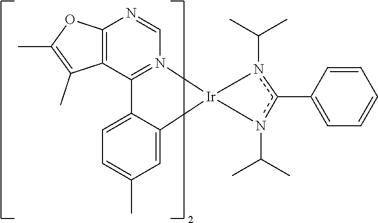

Organic Metal Compound (II)

10 mL of tetrahydrofuran (THF) and bromobenzene (3.2 mmole) were added into a reaction bottle. After cooling to −78° C., n-butyl lithium (n-BuLi) (3.2 mmole) was added dropwise into the reaction bottle and the result was stirred for 30 min. Next N,N-diisopropylcarbodiimide (3.2 mmole) was added into the reaction bottle at −78° C. After stirring for 30 min, the result was added dropwise into a solution including Compound (3) (0.8 mmole of Compound (3) was dissolved in 14 mL of tetrahydrofuran (THF)). Next, the reaction bottle was heated to reflux. After reacting for 8 hr, the result was concentrated by rotary evaporator, and then purified by column chromatography, obtaining Organic metal compound (II). The synthesis pathway of the above reaction was as follows:

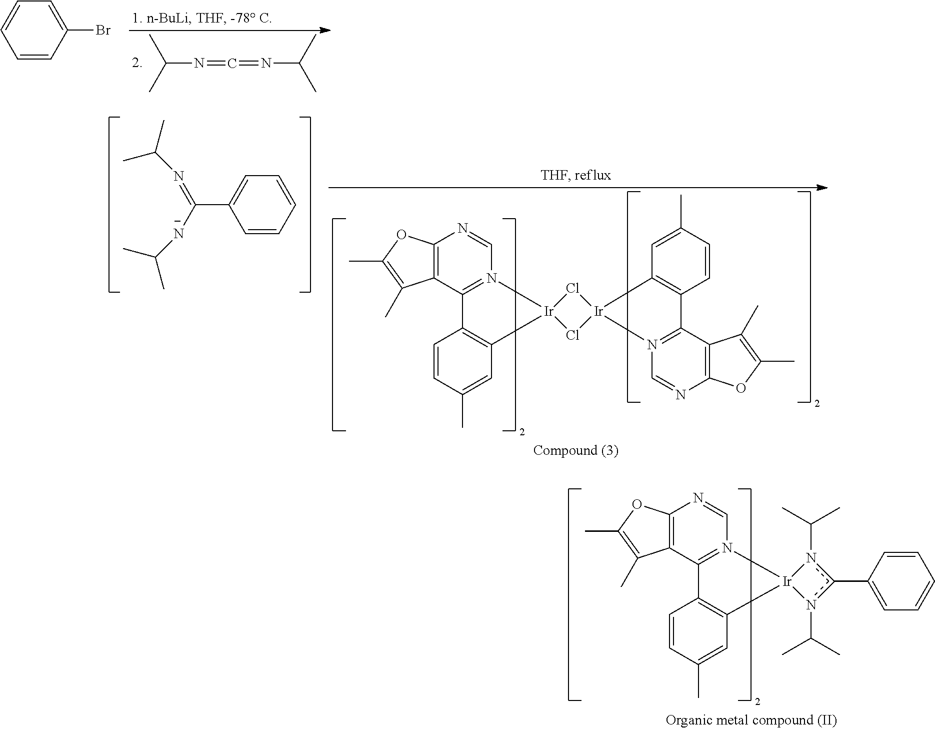

Preparation of Organic Metal Compound (III)

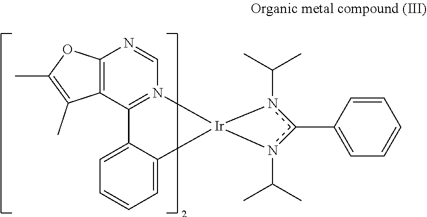

10 mL of tetrahydrofuran (THF) and bromobenzene (3.2 mmole) were added into a reaction bottle. After cooling to −78° C., n-butyl lithium (n-BuLi) (3.2 mmole) was added dropwise into the reaction bottle and the result was stirred for 30 min. Next N,N-diisopropylcarbodiimide (3.2 mmole) was added into the reaction bottle at −78° C. After stirring for 30 min, the result was added dropwise into a solution including compound (4) (0.8 mmole of Compound (4) was dissolved in 14 mL of tetrahydrofuran (THF)). Next, the reaction bottle was heated to reflux. After reacting for 8 hr, the result was concentrated by rotary evaporator, and then purified by column chromatography, obtaining Organic metal compound (III). The synthesis pathway of the above reaction was as follows:

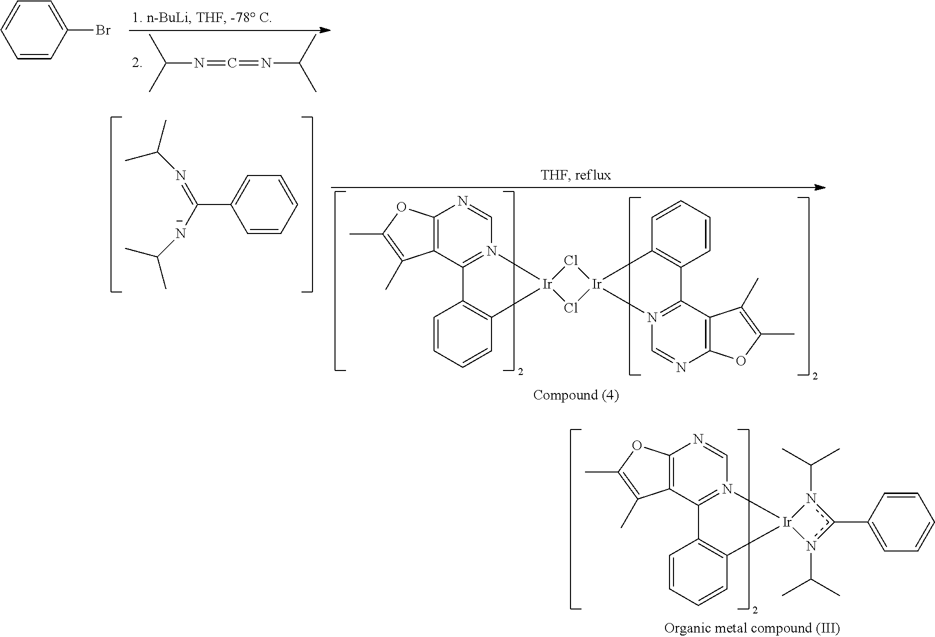

Preparation of Organic Metal Compound (IV)

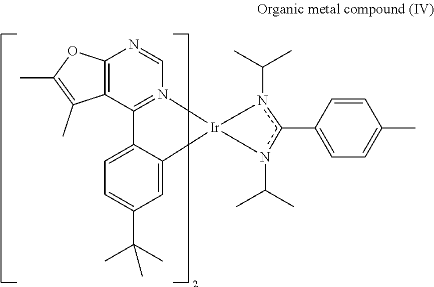

10 mL of tetrahydrofuran (THF) and 1-methyl-4-bromobenzene (3.2 mmole) were added into a reaction bottle. After cooling to −78° C., n-butyl lithium (n-BuLi) (3.2 mmole) was added dropwise into the reaction bottle and the result was stirred for 30 min. Next, N,N-diisopropylcarbodiimide (3.2 mmole) was added into the reaction bottle at −78° C. After stirring for 30 min, the result was added dropwise into a solution including compound (2) (0.8 mmole of Compound (2) was dissolved in 14 mL of tetrahydrofuran (THF)). Next, the reaction bottle was heated to reflux. After reacting for 8 hr, the result was concentrated by rotary evaporator, and then purified by column chromatography, obtaining Organic metal compound (IV). The synthesis pathway of the above reaction was as follows:

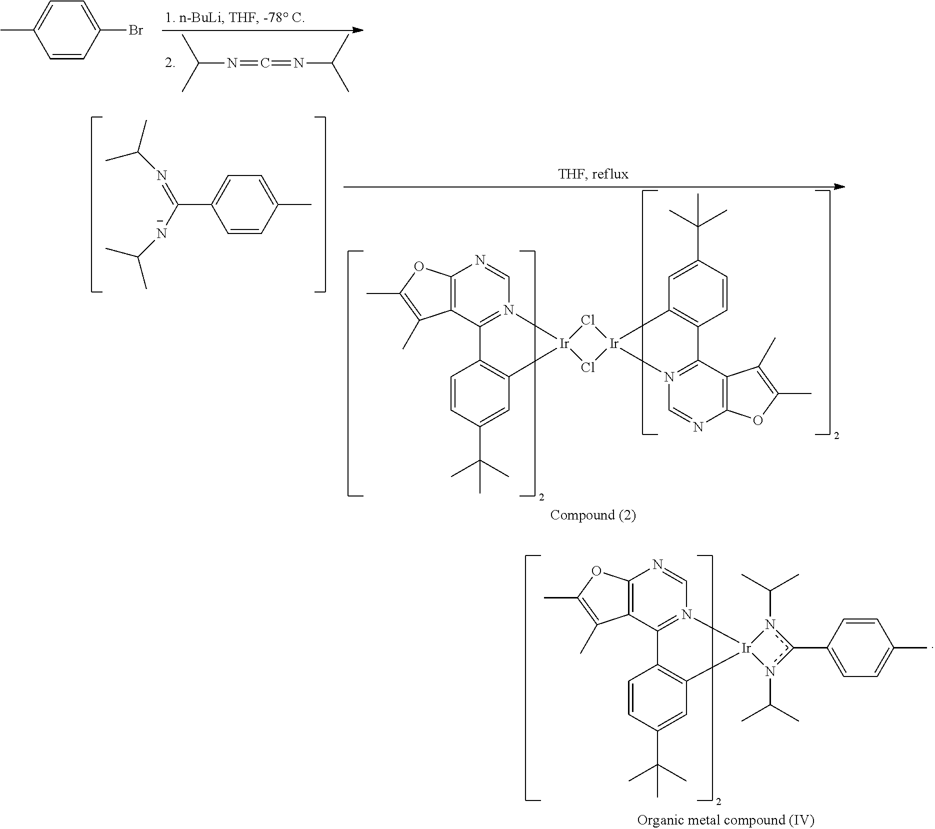

Preparation of Organic Metal Compound (XV)

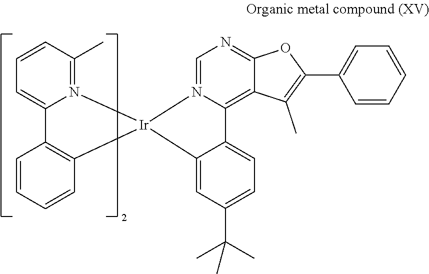

Compound (5) (1.54 mmole) and iridium trichloride (IrCl₃) (0.7 mmole), 2-methoxyethanol (15 mL) and water (5 mL) were added into a reaction bottle. Next, after removing moisture and purging nitrogen gas several times, the reaction bottle was heated to reflux. After reacting for 24 hr, the reaction bottle was cooled to room temperature. After adding water into the reaction bottle and filtrating, the filter cake was washed with water and methanol. After drying by a vacuum, Compound (6) was obtained. The synthesis pathway of the above reaction was as follows:

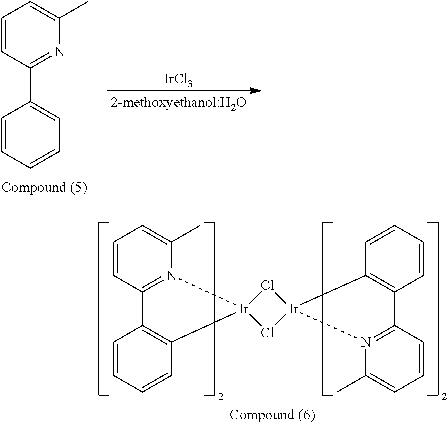

Next, silver trifluoroacetate (AgTFA) (15 mL) and methanol (50 mL) were added into a reaction bottle. Next, Compound (6) (10 mmole) and dichloromethane (100 mL) were added into the reaction bottle. Next, after removing moisture and purging nitrogen gas several times, the result was stirred for 18 hr at room temperature. Next, the result was dried, filtrated and concentrated, obtaining Compound (7). The synthesis pathway of the above reaction was as follows:

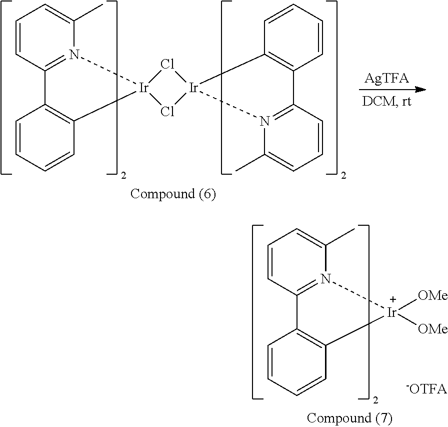

Next, Compound (7) (0.6 mmole), Compound (8) (0.9 mmole), 2-methoxyethanol (0.75 mL) and N,N-Dimethylformamide (0.75 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XV). The synthesis pathway of the above reaction was as follows:

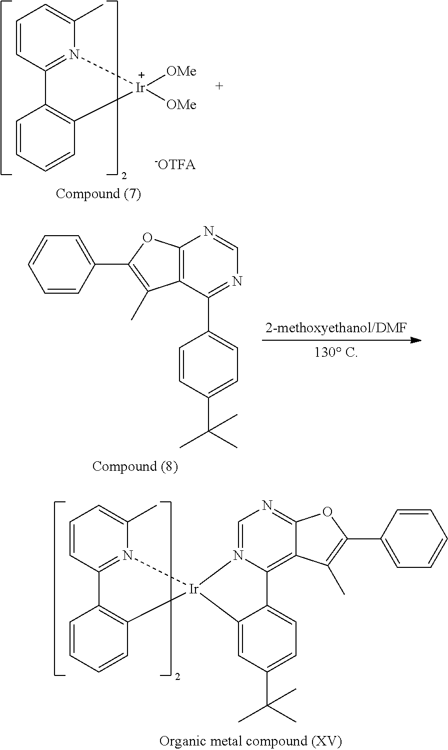

Preparation of Organic Metal Compound (XVI)

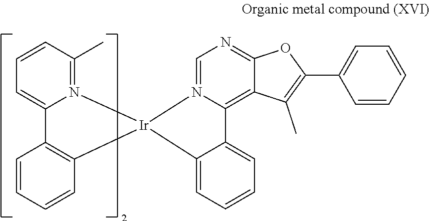

Next, Compound (7) (0.3 mmole), Compound (9) (0.45 mmole), 2-methoxyethanol (3.75 mL) and N,N-Dimethylformamide (3.75 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XVI). The synthesis pathway of the above reaction was as follows:

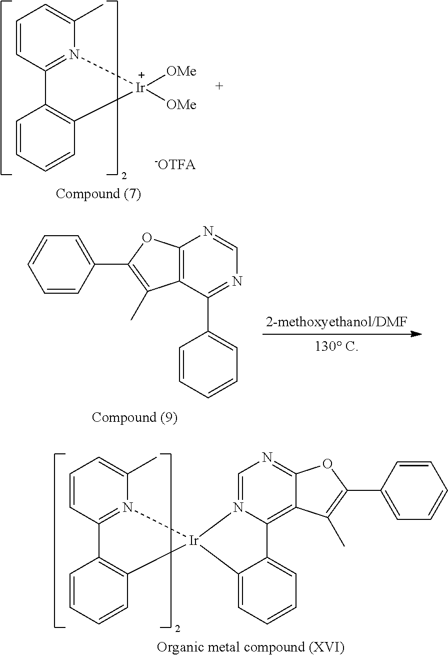

Preparation of Organic Metal Compound (XXVIII)

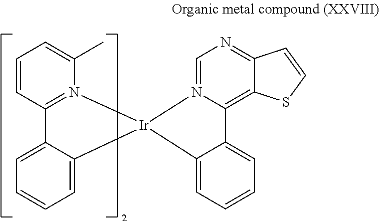

Next, Compound (7) (2 mmole), Compound (10) (3 mmole), 2-methoxyethanol (2.5 mL) and N,N-Dimethylformamide (2.5 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XXVIII). The synthesis pathway of the above reaction was as follows:

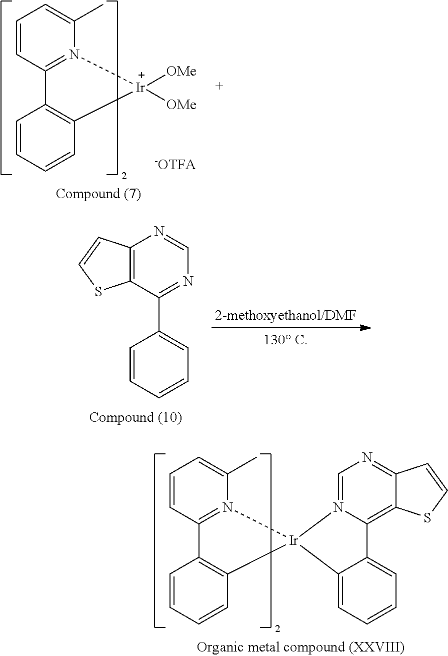

Preparation of Organic Metal Compound (XXIX)

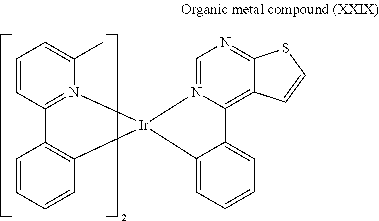

Next, Compound (7) (2 mmole), Compound (11) (3 mmole), 2-methoxyethanol (2.5 mL) and N,N-Dimethylformamide (2.5 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XXIX). The synthesis pathway of the above reaction was as follows:

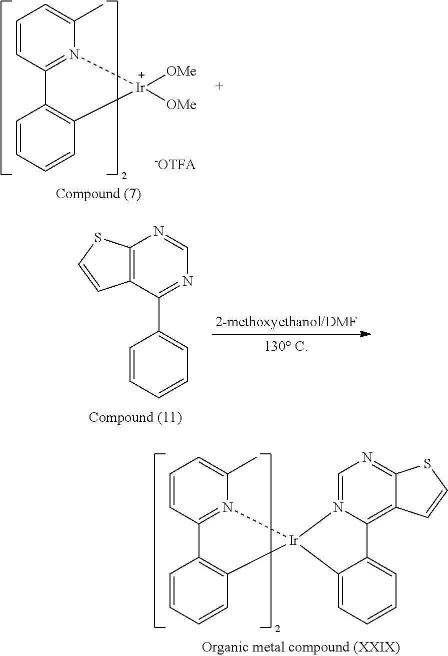

Preparation of Organic Metal Compound (XXXV)

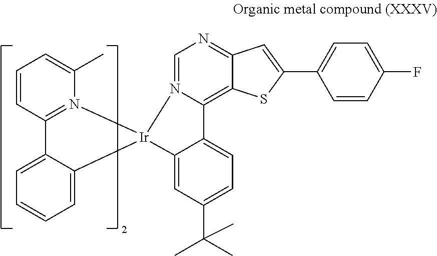

Next, Compound (7) (2 mmole), Compound (12) (3 mmole), 2-methoxyethanol (2.5 mL) and N,N-Dimethylformamide (2.5 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XXXV). The synthesis pathway of the above reaction was as follows:

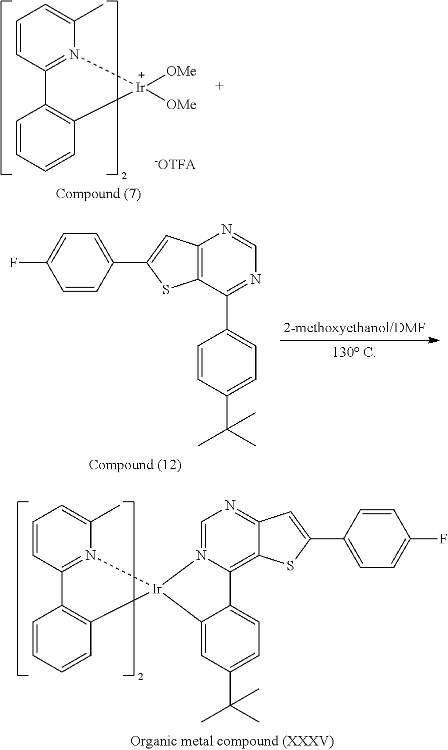

Preparation of Organic Metal Compound (XXXVIII)

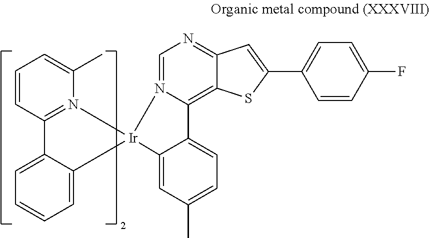

Next, Compound (7) (2 mmole), Compound (13) (3 mmole), 2-methoxyethanol (2.5 mL) and N,N-Dimethylformamide (2.5 mL) were added into a reaction bottle. Next, after removing moisture and purging nitrogen gas several times, the result was stirred for 18 hr at 130° C. After cooling to room temperature, water was added into the reaction bottle until a solid was precipitated. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography, obtaining Organic metal compound (XXXVIII). The synthesis pathway of the above reaction was as follows:

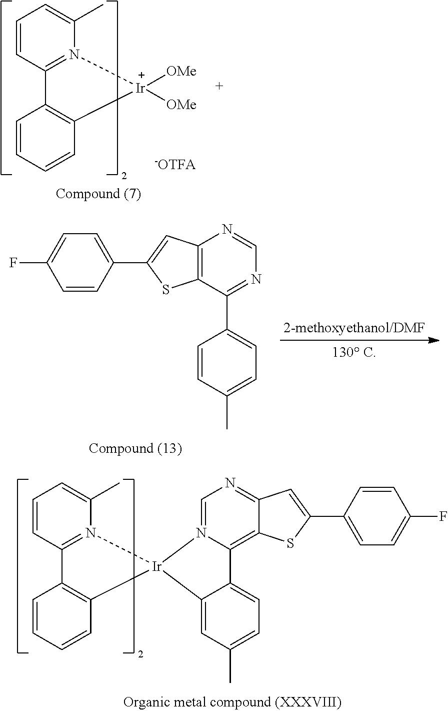

Preparation of Organic Metal Compound (XII)

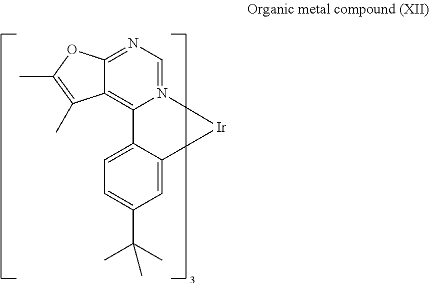

A reaction bottle was provided, and compound (2) (1 mmole), acetylacetone (4 mmole), sodium carbonate (2.2 mmole) and 2-methoxyethanol (10 mL) were added into the reaction bottle. Next, after removing moisture and purging nitrogen gas several times, the reaction bottle was heated at 120° C. After reacting for 3 hr, the reaction bottle was cooled to room temperature, and water was added into the reaction bottle. After filtrating, the filter cake was washed with n-hexane and water, and then the solid was dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography with dichloromethane/n-hexane (1:5) as the extraction solvent, obtaining Compound (14). The synthesis pathway of the above reaction was as follows:

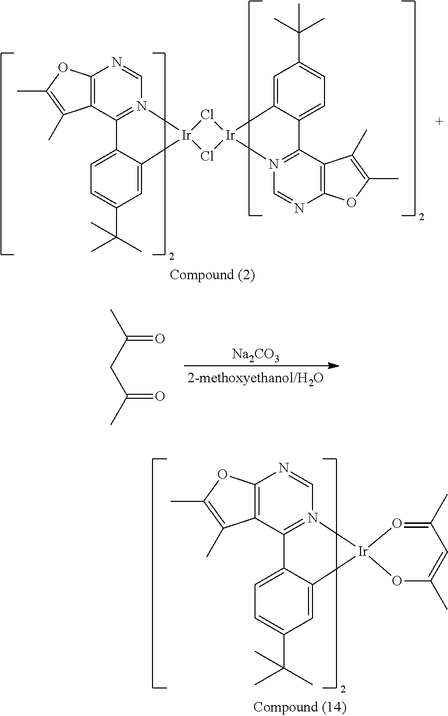

Next, Compound (14) (1 mmole), Compound (1) (2 mmole), and ethylene glycol (1 mL) were added into a reaction bottle. Next, the reaction bottle was heated to 160° C. in nitrogen atmosphere. After stirring for 48 hr, the reaction bottle was cooled to room temperature, and then water (5 mL) was added into the reaction bottle. After stirring and filtrating, the filter cake was washed with water. After drying, the solid was purified by column chromatography with ethyl acetate/n-hexane (1:10) as the extraction solvent, obtaining Organic metal compound (XII). The synthesis pathway of the above reaction was as follows:

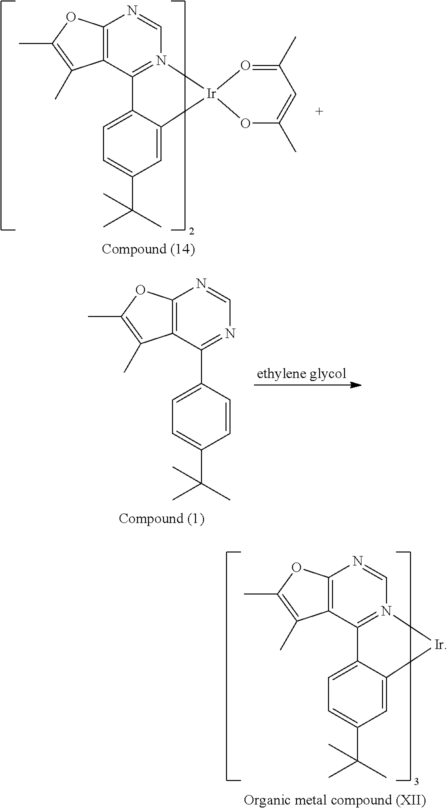

Next, the measurement results of nuclear magnetic resonance spectrometry of Organic metal compounds disclosed in Examples 1-4, 12, 15-16, 28-29, 35 and 38 are shown in Table 2.

TABLE 2

| | Nuclear magnetic resonance spectrum data |
|---|---|
| Organic metal | ¹H NMR (200 MHz, CDCl₃) δ 9.66 (d, 2H), 8.03 (d, 2H), |
| compound (I) | 7.29-7.40 (m, 5H), 6.83-6.85 (m, 2H), 6.42 (d, 2H), 3.23 |
| | (m, 2H), 2.55-2.57 (s, 12H), 1.00 (s, 18H), 0.63 (d, 6H), |
| | −0.09 (d, 6H). |
| Organic metal | ¹H NMR (200 MHz, CDCl₃) δ 9.66 (d, 2H), 8.03 (d, 2H), |
| compound (II) | 7.29-7.40 (m, 5H), 6.83-6.85 (m, 2H), 6.42 (d, 2H), 3.23 |
| | (m, 2H), 2.55-2.57 (s, 12H), 2.00 (s, 6H), 0.63 (d, 6H), |
| | −0.09 (d, 6H). |
| Organic metal | ¹H NMR (200 MHz, CDCl₃) δ 9.68 (d, 2H), 8.18 (d, 2H), |
| compound (III) | 7.28-7.42 (m, 5H), 6.80-6.83 (m, 2H), 6.66-6.70 (d, 2H), |
| | 6.41-6.43 (d, 2H), 3.21-3.24 (m, 2H), 2.59-2.61 (s, 12H), |
| | 0.65 (d, 6H), −0.09 (d, 6H). |
| Organic metal | ¹H NMR (200 MHz, CDCl₃) δ 9.66 (d, 2H), 8.01-8.03 (d, 2H), |
| compound (IV) | 7.18-7.22 (m, 4H), 6.83-6.85 (d, 2H), 6.41-6.42 |
| | (d, 2H), 3.23-3.25 (m, 2H), 2.55-2.57 (d, 12H), 2.35 |
| | (s, 2H), 1.00 (s, 18H), 0.62 (d, 6H), −0.09 (d, 6H). |
| Organic metal | ¹H NMR (200 MHz, CDCl₃, δ): 8.04 (d, 3H), 7.76 (s, 3H), |
| compound (XII) | 6.97 (d, 3H), 6.85 (s, 3H), 2.50 (s, 9H), 2.46 (s, 9H), 1.07 |
| | (s, 27H). |
| Organic metal | ¹H-NMR (200 MHz, CDCl₃, δ): 8.07 (d, 2H), 7.94-7.96 |
| compound (XV) | (d, 2H), 7.85-7.87 (d, 2H), 7.80-7.82 (d, 2H), 7.74-7.76 |
| | (m, 6H), 7.41-7.59 (m, 12H), 6.90-6.93 (m, 6H), 6.80 (t, 2H), |
| | 6.75 (t, 4H), 6.7 (d, 2H), 6.65 (t, 2H), 6.60 (t, 4H), |
| | 2.71 (s, 6H), 2.04 (s, 6H), 1.96 (s, 6H), 1.00 (s, 18H). |
| Organic metal | ¹H-NMR (200 MHz, CDCl₃, δ): 8.11 (d, 2H), 8.04-8.05 |
| compound (XVI) | (d, 2H), 7.84-7.86 (d, 2H), 7.71-7.77 (m, 8H), 7 46-7.55 |
| | (m, 10H), 7.41-7.42 (m, 2H), 6.87-6.93 (m, 6H), 6.80 |
| | (dd, 4H), 6.75 (t, 6H), 6.65 (t, 2H), 6.55 (d, 4H), 2.70 (s, 6H), |
| | 1.98 (s, 6H), 1.96 (s, 6H). |
| Organic metal | ¹H-NMR (200 MHz, CDCl₃, δ): 8.35 (s, 2H), 8.11 (d, 2H), |
| compound (XXVIII) | 7.83-7.85 (m, 4H), 7.78-7.80 (d, 2H), 7.71-7.73 (d, 2H), |
| | 7.51-7.57 (m, 4H), 7.42-7.46 (m, 4H), 7.00-7.03 |
| | (t, 2H), 6.72-6.93 (m, 12H), 6.70 (d, 2H), 6.60 (t, 2H), |
| | 6.55 (d, 2H), 6.25 (d, 2H), 1.98 (s, 6H), 1.86 (s, 6H) |
| Organic metal | ¹H-NMR (200 MHz, CDCl₃, δ): 8.26 (s, 2H), 8.14-8.16 |
| compound (XXIX) | (d, 2H), 8.07-8.08 (d, 2H), 7.83-7.84 (d, 2H), 7.78-7.79 |
| | (d, 2H), 7.71-7.72 (d, 2H), 7.51-7.56 (m, 6H), 7.43-7.46 |
| | (t, 2H), 6.65-6.98 (m, 16H), 6.60 (t, 2H), 6.53 (d, 2H), |
| | 6.32 (d, 2H), 1.97 (s, 6H), 1.88 (s, 6H). |
| Organic metal | ¹H-NMR (200 MHz, CDCl₃, δ): 8.26 (s, 2H), 8.01 (d, 2H), |
| compound (XXXV) | 7.83-7.85 (m, 4H), 7.74-7.76 (m, 6H), 7.55-7.61 (m, 4H), |
| | 7.51 (s, 2H), 7.41-7.44 (t, 2H), 7.16-7.19 (t, 4H), |
| | 7.03-7.05 (d, 2H), 6.90-6.93 (m, 4H), 6.75-6.83 (m, 6H), |
| | 6.68 (d, 2H), 6.58-6.63 (m, 4H), 6.35 (d, 2H), 2.03 |
| | (s, 6H), 1.93 (s, 6H), 1.03 (s, 18H). |
| Organic metal | ¹H-NMR (200 MHz, CDCl₃, δ): 8.30 (s, 2H), 8.01-8.03 |
| compound (XXXVIII) | (d, 2H), 7.85-7.87 (d, 2H), 7.80-7.82 (d, 2H), 7.73-7.78 |
| | (m, 6H), 7.52-7.59 (m, 6H), 7.46-7.49 (t, 2H), 7.16-7.20 |
| | (t, 4H), 6.72-6.94 (m, 14H), 6.62-6.65 (t, 2H), 6.60 |
| | (s, 2H), 6.56 (d, 2H), 6.35 (d, 2H), 2.11 (s, 6H), 1.99 (s, 6H), |
| | 1.93 (s, 6H). |

Next, Organic metal compounds (I)-(IX), Organic metal compounds (XIII)-(XIX), Organic metal compounds (XXI) and Organic metal compounds (XXIII)-(XXXIX) of Examples 1-9, 13-19, 21 and 23-39 were individually dissolved into dichloromethane, obtaining solutions with a concentration of 10⁻⁵M. Next, the photoluminescence (PL) spectra of the solutions were measured, and the results are shown in Table 3.

TABLE 3

| | Maximum |
|---|---|
| | luminous |
| | intensity peak |
| | (Emission λmax) |
| Organic metal compound (I) | 609 nm |
| Organic metal compound (II) | 601 nm |
| Organic metal compound (III) | 612 nm |
| Organic metal compound (IV) | 611 nm |
| Organic metal compound (V) | 605 nm |
| Organic metal compound (VI) | 599 nm |
| Organic metal compound (VII) | 584 nm |
| Organic metal compound (VIII) | 611 nm |
| Organic metal compound (IX) | 630 nm |
| Organic metal compound (XIII) | 564 nm |
| Organic metal compound (XIV) | 586 nm |
| Organic metal compound (XV) | 583 nm |
| Organic metal compound (XVI) | 593 nm |
| Organic metal compound (XVII) | 627 nm |
| Organic metal compound (XVIII) | 608 nm |
| Organic metal compound (XIX) | 646 nm |
| Organic metal compound (XXI) | 609 nm |
| Organic metal compound (XXIII) | 643 nm |
| Organic metal compound (XXIV) | 561 nm |
| Organic metal compound (XXV) | 594 nm |
| Organic metal compound (XXVI) | 595 nm |
| Organic metal compound (XXVII) | 607 nm |
| Organic metal compound (XXVIII) | 614 nm |
| Organic metal compound (XXIX) | 603 nm |
| Organic metal compound (XXX) | 598 nm |
| Organic metal compound (XXXI) | 640 nm |
| Organic metal compound (XXXII) | 629 nm |
| Organic metal compound (XXXIII) | 616 nm |
| Organic metal compound (XXXIV) | 625 nm |
| Organic metal compound (XXXV) | 634 nm |
| Organic metal compound (XXXVI) | 636 nm |
| Organic metal compound (XXXVII) | 642 nm |
| Organic metal compound (XXXVIII) | 629 nm |
| Organic metal compound (XXXIX) | 636 nm |

As shown in Table 3, the organic metal compounds of the disclosure having a structure represented by Formula (I) or Formula (II) have a maximum luminous intensity peak between 561 nm and 646 nm (i.e. the organic metal compounds of the disclosure are red or yellowish red phosphorescent materials). In addition, when introducing phenyl group or alkyl group (such as tert-butyl group) into thiopyrimidine or furopyrimidine ligand, the obtained organic metal compound exhibits a red-shifted maximum luminous intensity peak, as shown in Table 3.

Next, the sublimation temperature and sublimation yield of Organic metal compounds of disclosed in Examples 1-4, 15, 16 and 28 were measured, and the results are shown in Table 4:

TABLE 4

| | Sublimation | Sublimation |
|---|---|---|
| | temperature | yield |
| | (° C.) | (%) |
| Organic metal compound (I) | 240 | 86 |
| Organic metal compound (II) | 230 | 86 |
| Organic metal compound (III) | 230 | 82 |
| Organic metal compound (IV) | 230 | 93 |
| Organic metal compound (XV) | 260 | 92 |
| Organic metal compound (XXI) | 245 | 81 |
| Organic metal compound (XXVIII) | 260 | 88 |

As shown in Table 4, since the organic metal compound of the disclosure has thiopyrimidine-based (or furopyrimidine-based) ligand and phenylpyridine-based ligand (such as methylphenylpyridine (mppy) ligand) (or diisopropyl carbodiimide ligand), the obtained six-coordinate iridium compound exhibits high thermal stability and is suitable to be purified by sublimation process. The organic light-emitting device employing the organic metal compound of the disclosure exhibits high operating lifespan and luminescent efficiency.

Organic Light-Emitting Device

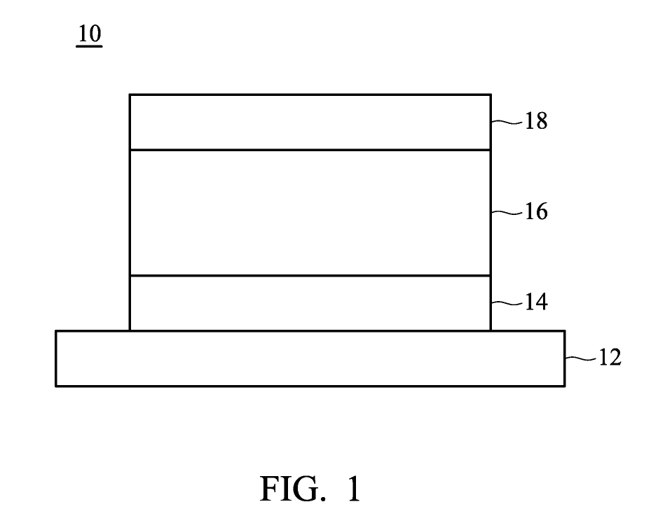

FIG. 1 shows an embodiment of an organic light-emitting device 10. The organic light-emitting device 10 includes a substrate 12, a bottom electrode 14, an organic light-emitting element 16, and a top electrode 18, as shown in FIG. 2. The organic light-emitting device can be a top-emission, bottom-emission, or dual-emission device. The substrate 12 can be a glass, plastic, or semiconductor substrate. Suitable materials for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent.

The organic light-emitting element 16 at least includes an emission layer, and can further include a hole injection layer, a hole transport layer, an electron transport layer, and an electron injection layer. In an embodiment of the disclosure, at least one layer of the organic light-emitting element 16 includes the aforementioned organic metal compound.

According to another embodiment of the disclosure, the organic light-emitting device can be a phosphorescent organic light-emitting device, and the emission layer of the organic light-emitting element 16 can include a host material and a phosphorescence dopant, wherein the phosphorescence dopant can include the aforementioned organic metal compound having the structure represented by Formula (I) or Formula (II). The emission layer emits blue or cyan light under a bias voltage. The dose of the dopant is not limited and can optionally be modified by a person of ordinary skill in the field.

In order to clearly disclose the organic light-emitting devices of the disclosure, the following examples (having an emitting layer employing the organic metal compounds of the disclosure) are intended to illustrate the disclosure more fully without limiting their scope, since numerous modifications and variations will be apparent to those skilled in this art.

### Example 40

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min. Next, PEDOT (poly(3,4)-ethylendioxythiophen):PSS (e-polystyrenesulfonate) was coated on the ITO film by a blade and spin coating process (with a rotation rate of 500 rpm for 5 sec and a rotation rate of 2000 rpm for 30 sec) and baked at 130° C. for 10 min to form a PEDO:PSS film serving as a hole injection layer (with a thickness of 40 nm). Next, TAPC (1,1-bis[4-[N,N′-di (p-tolyl)amino]phenyl]cyclobexane, with a thickness of 35 nm), TCTA (4,4′,4′-tri (N-carbazolyl)triphenylamine) doped with Organic metal compound (I) (the weight ratio between TCTA and Organic metal compound (I) was 100:6, with a thickness of 10 nm), TmPyPB (1,3,5-tri[(3-pyridyl)-phen-3-yl]benzene, with a thickness of 42 nm), LiF (with a thickness of 0.5 nm), and Al (with a thickness of 120 nm) were subsequently formed on the PEDO:PSS film at 10⁻⁶ torr, obtaining Organic light-emitting device (I) after encapsulation. The materials and layers of Organic light-emitting device (I) are described in the following: ITO/PEDOT:PSS/TAPC/TCTA:Organic metal compound (I)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (I) were measured by a spectra colorimeter and a luminance meter. The results are shown in Table 5.

### Example 41

Example 41 was performed in the same manner as in Example 40 except that Organic metal compound (II) was substituted for Organic metal compound (I), obtaining Organic light-emitting device (II). The materials and layers of Organic light-emitting device (II) are described in the following: ITO/PEDOT:PSS/TAPC/TCTA:Organic metal compound (II)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (II) were measured by a spectra colorimeter and a luminance meter. The results are shown in Table 5.

### Example 42

Example 42 was performed in the same manner as in Example 40 except that Organic metal compound (III) was substituted for Organic metal compound (I), obtaining Organic light-emitting device (III). The materials and layers of Organic light-emitting device (III) are described in the following: ITO/PEDOT:PSS/TAPC/TCTA:Organic metal compound (III)(6%)/TmPyPB/LiF/Al

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (III) were measured by a spectra colorimeter and a luminance meter. The results are shown in Table 5.

### Example 43

Example 43 was performed in the same manner as in Example 40 except that Organic metal compound (IV) was substituted for Organic metal compound (I), obtaining Organic light-emitting device (IV). The materials and layers of Organic light-emitting device (IV) are described in the following: ITO/PEDOT:PSS/TAPC/TCTA:Organic metal compound (IV)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (IV) were measured by a spectra colorimeter and a luminance meter. The results are shown in Table 5.

### Example 44

Example 44 was performed in the same manner as in Example 40 except that Organic metal compound (XV) was substituted for Organic metal compound (I), obtaining Organic light-emitting device (V). The materials and layers of Organic light-emitting device (V) are described in the following: ITO/PEDOT:PSS/TAPC/TCTA:Organic metal compound (XV)(6%)/TmPyPB/LiF/Al

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (V) were measured by a spectra colorimeter and a luminance meter. The results are shown in Table 5.

### Example 45

Example 45 was performed in the same manner as in Example 40 except that Organic metal compound (XVI) was substituted for Organic metal compound (I), obtaining Organic light-emitting device (VI). The materials and layers of Organic light-emitting device (VI) are described in the following: ITO/PEDOT:PSS/TAPC/TCTA:Organic metal compound (XVI)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (VI) were measured by a spectra colorimeter and a luminance meter. The results are shown in Table 5.

### Example 46

Example 46 was performed in the same manner as in Example 40 except that Organic metal compound (XXVIII) was substituted for Organic metal compound (I), obtaining Organic light-emitting device (VII). The materials and layers of Organic light-emitting device (VII) are described in the following: ITO/PEDOT:PSS/TAPC/TCTA:Organic metal compound (XXVIII)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (VII) were measured by a spectra colorimeter and a luminance meter. The results are shown in Table 5.

### Example 47

Example 47 was performed in the same manner as in Example 40 except that Organic metal compound (XXIX) was substituted for Organic metal compound (I), obtaining Organic light-emitting device (VIII). The materials and layers of Organic light-emitting device (VIII) are described in the following: ITO/PEDOT:PSS/TAPC/TCTA:Organic metal compound (XXIX)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (VIII) were measured by a spectra colorimeter and a luminance meter. The results are shown in Table 5.

### Example 48

Example 48 was performed in the same manner as in Example 40 except that Organic metal compound (XXXV) was substituted for Organic metal compound (I), obtaining Organic light-emitting device (IX). The materials and layers of Organic light-emitting device (IX) are described in the following: ITO/PEDOT:PSS/TAPC/TCTA:Organic metal compound (XXXV)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (IX) were measured by a spectra colorimeter and a luminance meter. The results are shown in Table 5.

### Example 49

Example 48 was performed in the same manner as in Example 40 except that Organic metal compound (XXXVIII) was substituted for Organic metal compound (I), obtaining Organic light-emitting device (X). The materials and layers of Organic light-emitting device (X) are described in the following: ITO/PEDOT:PSS/TAPC/TCTA:Organic metal compound (XXXVIII)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinate (x, y)) of Organic light-emitting device (X) were measured by a spectra colorimeter and a luminance meter. The results are shown in Table 5.

TABLE 5

| | | | current | power | | |
|---|---|---|---|---|---|---|
| | voltage | brightness | efficiency | efficiency | | Emission |
| | (V) | (cd/m2) | (cd/A) | (lm/W) | C.I.E coordinate | λmax (nm) |
| Organic | 4.0 | 1000 | 24.5 | 19.4 | (0.61, 0.39) | 600 |
| light-emitting | | | | | | |
| device (I) | | | | | | |
| Organic | 3.6 | 1000 | 29.0 | 25.6 | (0.59, 0.41) | 592 |
| light-emitting | | | | | | |
| device (II) | | | | | | |
| Organic | 4.0 | 1000 | 25.8 | 20.1 | (0.62, 0.38) | 604 |
| light-emitting | | | | | | |
| device (III) | | | | | | |
| Organic | 3.9 | 1000 | 25.5 | 20.6 | (0.62, 0.38) | 604 |
| light-emitting | | | | | | |
| device (IV) | | | | | | |
| Organic | 3.3 | 1000 | 62.5 | 58.8 | (0.54, 0.46) | 580 |
| light-emitting | | | | | | |
| device (V) | | | | | | |
| Organic | 3.4 | 1000 | 45.5 | 42.0 | (0.60, 0.40) | 592 |
| light-emitting | | | | | | |
| device (VI) | | | | | | |
| Organic | 3.5 | 1000 | 24.2 | 21.9 | (0.62, 0.38) | 604 |
| light-emitting | | | | | | |
| device | | | | | | |
| (VII) | | | | | | |
| Organic | 3.6 | 1000 | 28.2 | 24.6 | (0.62, 0.38) | 604 |
| light-emitting | | | | | | |
| device | | | | | | |
| (VIII) | | | | | | |
| Organic | 3.4 | 1000 | 24.8 | 22.9 | (0.65, 0.34) | 628 |
| light-emitting | | | | | | |
| device (IX) | | | | | | |
| Organic | 3.5 | 1000 | 24.2 | 21.7 | (0.62, 0.38) | 628 |
| light-emitting | | | | | | |
| device (X) | | | | | | |

In addition, the lifespan (the time before falling to 50% of original brightness (1000 cd/m2)) (LT50) of Organic light-emitting device (III) and Organic light-emitting devices (V)-(X) were measured, and the results are shown in Table 6.

TABLE 6

| | Lifespan |
|---|---|
| | (hours) |
| Organic light-emitting | 210,000 |
| device (III) | |
| Organic light-emitting | >500,000 |
| device (V) | |
| Organic light-emitting | >500,000 |
| device (VI) | |
| Organic light-emitting | >200,000 |
| device (VII) | |
| Organic light-emitting | >300,000 |
| device (VIII) | |
| Organic light-emitting | >200,000 |
| device (IX) | |
| Organic light-emitting | >200,000 |
| device (X) | |

As shown in Table 5, the organic light-emitting device employing the organic metal compound of the disclosure emits red light under a bias voltage and exhibits higher luminescent efficiency.

In addition, as shown in Table 6, the organic light-emitting device employing the organic metal compound of the disclosure can have an operating lifespan (LT50) greater than 200,000 hr. Accordingly, due to the specific ligand introduced into the organic metal compound of the disclosure, the organic light-emitting device employing the organic metal compound of the disclosure exhibits higher operating lifespan and luminescent efficiency.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organic metal compound, having a structure of Formula (I) or Formula (II): 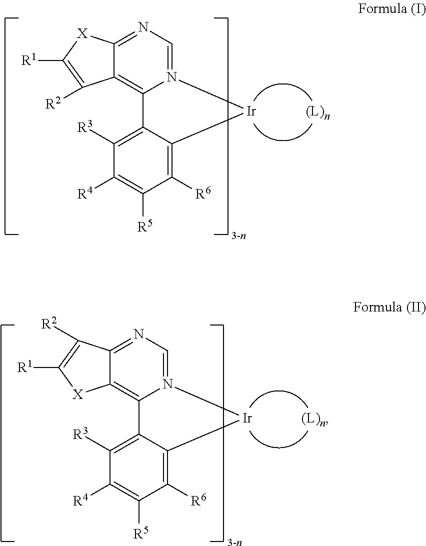
wherein X is O or S; R¹ is independently hydrogen, halogen, C₁₋₈ alkyl group, C₁₋₈ haloalkyl group, C₁₋₈ alkoxy group, C₅₋₁₀ cycloalkyl group, or 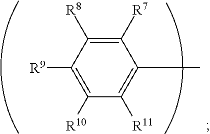
R², R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₈ haloalkyl group, C₆₋₁₂ aryl group, or C₁₋₈ alkoxy group; L is 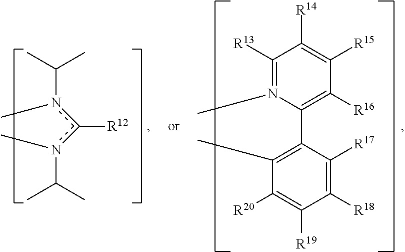
wherein R¹² is 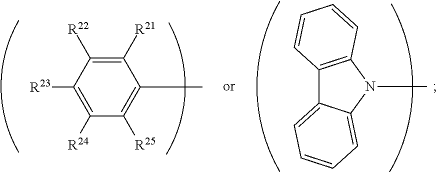
R¹³, R¹⁴, R¹⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group; R²¹, R²², R²³, R²⁴ and R²⁵ are independently hydrogen, halogen, C₁₋₈ alkyl group, C₁₋₈ haloalkyl group, or C₁₋₈ alkoxy group; and, n is 0, 1, or 2.

2. The organic metal compound as claimed in claim 1, wherein R¹, R², R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

3. The organic metal compound as claimed in claim 1, wherein R¹ is 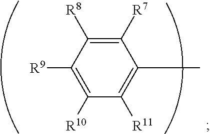
wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

4. The organic metal compound as claimed in claim 1, wherein L is 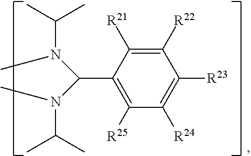
wherein R²¹, R²², R²³, R²⁴ and R²⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

5. The organic metal compound as claimed in claim 1, wherein L is 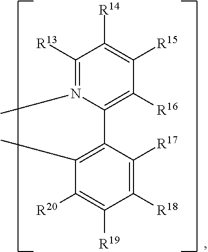
wherein R¹³, R¹⁴, R¹⁵, R¹⁶, R¹⁷, R¹⁸, R¹⁹ and R²⁰ is independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

6. The organic metal compound as claimed in claim 1, wherein the organic metal compound is 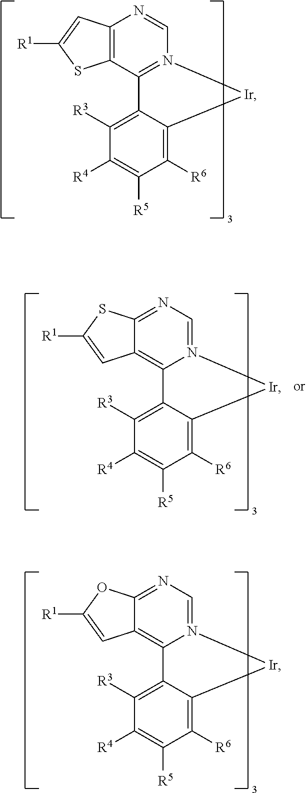
wherein R¹ is independently hydrogen, halogen, C₁₋₈ alkyl group, C₁₋₈ haloalkyl group, C₁₋₈ alkoxy group, C₅₋₁₀ cycloalkyl group, or 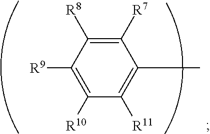
R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group.

7. The organic metal compound as claimed in claim 6, wherein R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

8. The organic metal compound as claimed in claim 6, wherein R¹ is 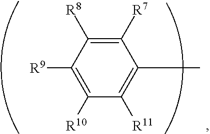
wherein R⁷, R⁸, R⁹, R¹⁰ and R¹¹ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

9. The organic metal compound as claimed in claim 1, wherein the organic metal compound is 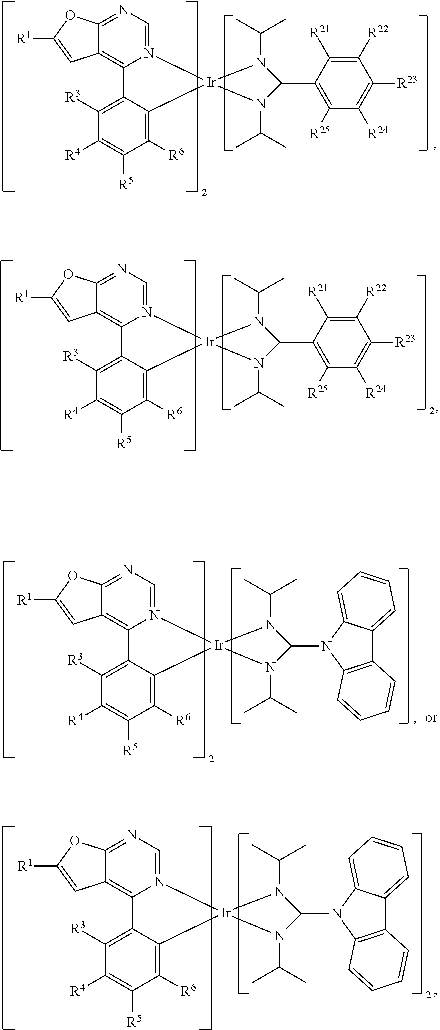
wherein R¹ is independently hydrogen, halogen, C₁₋₈ alkyl group, C₁₋₈ haloalkyl group, C₁₋₈ alkoxy group, C₅₋₁₀ cycloalkyl group, or 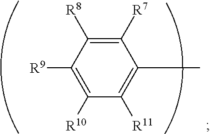
R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R²¹, R²², R²³, R²⁴ and R²⁵ are independently hydrogen, halogen, C₁₋₈ alkyl group, C₁₋₈ haloalkyl group, or C₁₋₈ alkoxy group.

10. The organic metal compound as claimed in claim 9, wherein R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

11. The organic metal compound as claimed in claim 9, wherein R²¹, R²², R²³, R²⁴ and R²⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

12. The organic metal compound as claimed in claim 1, wherein the organic metal compound is 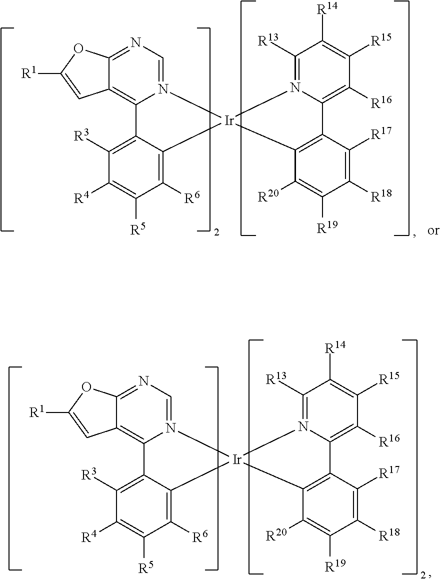
wherein R¹ is independently hydrogen, halogen, C₁₋₈ alkyl group, C₁₋₈ haloalkyl group, C₁₋₈ alkoxy group, C₅₋₁₀ cycloalkyl group, or 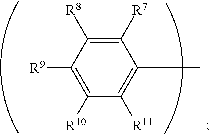
R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R¹³, R¹⁴, R¹⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group.

13. The organic metal compound as claimed in claim 12, wherein R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

14. The organic metal compound as claimed in claim 12, wherein R¹³, R¹⁴, R¹⁵, R¹⁶, R¹⁷, R¹⁸, R¹⁹ and R²⁰ is independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

15. The organic metal compound as claimed in claim 1, wherein the organic metal compound is 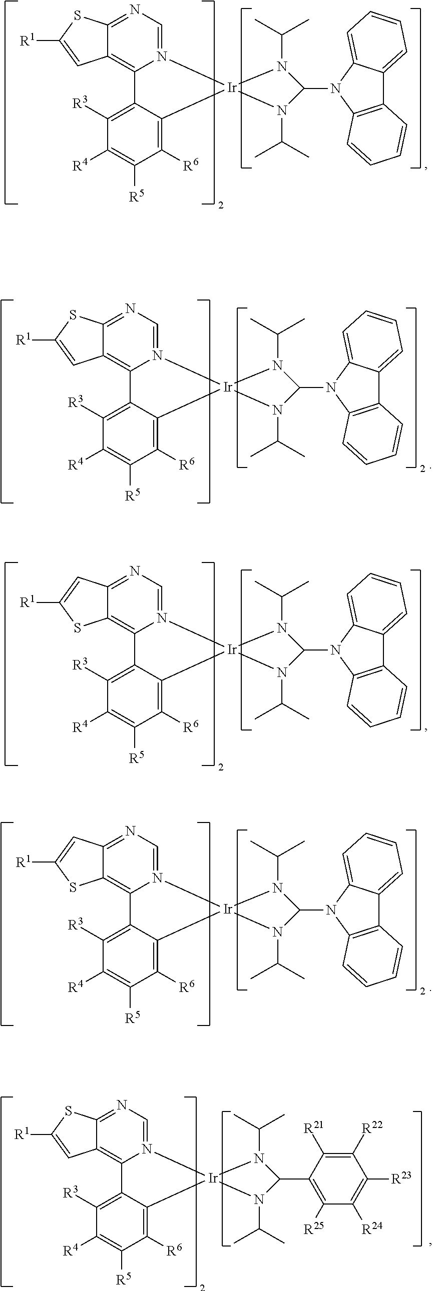 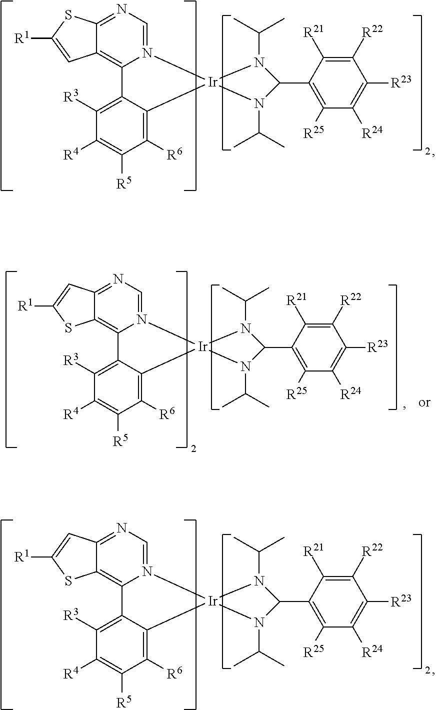
wherein R¹ is independently hydrogen, halogen, C₁₋₈ alkyl group, C₁₋₈ haloalkyl group, C₁₋₈ alkoxy group, C₅₋₁₀ cycloalkyl group, or 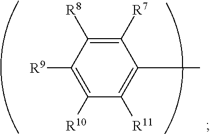
R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; R⁷, R⁸, R⁹, R¹⁰ and R¹¹ are independently hydrogen, halogen, C₁₋₈ alkyl group, C₁₋₈ haloalkyl group, C₆₋₁₂ aryl group, or C₁₋₈ alkoxy group; and, R²¹, R²², R²³, R²⁴ and R²⁵ are independently hydrogen, halogen, C₁₋₈ alkyl group, C₁₋₈ haloalkyl group, or C₁₋₈ alkoxy group.

16. The organic metal compound as claimed in claim 15, wherein R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

17. The organic metal compound as claimed in claim 15, wherein R²¹, R²², R²³, R²⁴ and R²⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, or hexyloxy group.

18. The organic metal compound as claimed in claim 1, wherein the organic metal compound is 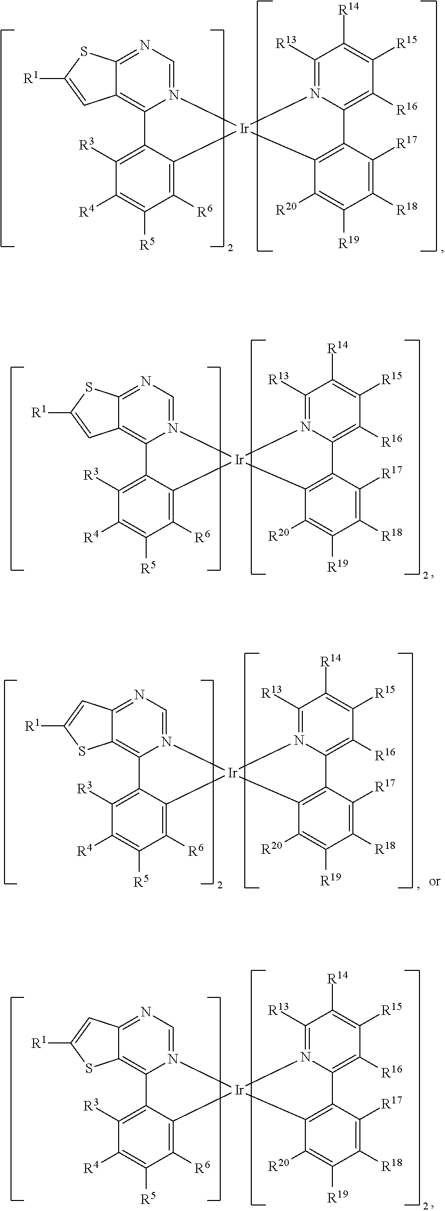
wherein R¹ is independently hydrogen, halogen, C₁₋₈ alkyl group, C₁₋₈ haloalkyl group, C₁₋₈ alkoxy group, C₅₋₁₀ cycloalkyl group, or 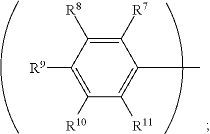
R³, R⁴, R⁵ and R⁶ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R³, R⁴, R⁵ and R⁶ are optionally combined with the carbon atoms to which they are attached, to form a cycloalkyl group, or an aryl group; wherein R⁷, R⁸, R⁹, R¹⁰ and R¹¹ are independently hydrogen, halogen, C₁₋₈ alkyl group, C₁₋₈ haloalkyl group, or C₁₋₈ alkoxy group; and, R¹³, R¹⁴, R¹⁵, R¹⁶, R¹⁷, R¹⁸, R¹⁹ and R²⁰ is independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or two adjacent groups of R¹³, R¹⁴, R¹⁵, R¹⁶, R¹⁷, R¹⁸, R¹⁹ and R²⁰ are optionally combined with the carbon atoms to which they are attached, to form a cycloalkyl group, or an aryl group.

19. The organic metal compound as claimed in claim 18, wherein R¹, R³, R⁴, R⁵ and R⁶ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

20. The organic metal compound as claimed in claim 18, wherein R¹³, R¹⁴, R¹⁵, R¹⁶, R¹⁷, R¹⁸, R¹⁹ and R²⁰ is independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

21. An organic light-emitting device, comprising:
a pair of electrodes; and
an organic light-emitting element, disposed between the electrodes, wherein the organic light-emitting element comprises the organic metal compound as claimed in claim 1.
